(19) United States
(12) Patent Application Publication
(10) Pub. No.: US 2026/0305116 A1
(43) Pub. Date: Oct. 1, 2026

(54) LIGHT EMITTING DISPLAY DEVICE

(71) Applicant: LG Display Co., Ltd., Seoul (KR)

(72) Inventors: Geonhyeong Kim, Paju-si (KR); HoSung Han, Paju-si (KR)

(73) Assignee: LG Display Co., Ltd., Seoul (KR)

(21) Appl. No.: 19/431,108

(22) Filed: Dec. 23, 2025

(30) Foreign Application Priority Data
Mar. 27, 2025 (KR) 10-2025-0039902

(51) Int. Cl. H10K 59/65; H10K 59/40; H10K 59/80

(52) U.S. Cl. CPC H10K 59/65; H10K 59/40; H10K 59/8731; H10K 59/8791

(57) ABSTRACT

The light emitting display device according to the present disclosure comprises: a cover panel, an adhesive layer and a display panel. The cover panel includes: a cover plate, a transparent area, a print area, a black pattern and a flattening layer. The cover plate includes a display area and a non-display area surrounding the display area. The transparent area is disposed within the display area of the cover plate. The print area surrounds the transparent area and divides the transparent area from the display area. The black pattern is disposed at the print area on an inner surface of the cover plate. The flattening layer is deposited on entire inner surface of the cover plate as covering the black pattern. The adhesive layer is deposited on the flattening layer. The display panel is attached to the adhesive layer.

### CROSS-REFERENCE TO RELATED APPLICATION

This application claims the benefit of Korean Patent Application No. 10-2025-0039902, filed on Mar. 27, 2025, which is hereby incorporated by reference as if fully set forth herein.

### BACKGROUND

### Field of the Disclosure

The present disclosure relates to a light emitting display device. In particular, the present disclosure relates to a display device having a cover plate with a printed pattern at an inner surface of the cover plate.

### Discussion of the Related Art

Light emitting display devices may be made ultra-thin and/or have excellent flexibility, so they may be applied to various products in various fields. An optical device such as a camera may be disposed on the back of the display panel included in the light emitting display device, and may be used for various purposes. In particular, by forming a through-hole in the display panel, an optical device may be applied without optical loss. This structure may be required to prevent moisture or air from penetrating into the interior through the through-hole.

Furthermore, the cover plate (or cover window) placed on the upper most layer of the display panel may have a printed layer with a black pattern covering the border of the through-hole and/or a company logo, etc. The cover plate having such a print layer may be directly attached to the upper most surface of the display panel using a transparent adhesive material. Due to the step difference caused by the pattern printed on the print layer, moisture or air may intrude via the surface of the cover plate. When moisture or air remains around the pattern printed on the print layer of the cover plate, bubble defects may occur in the adhesive layer, which may cause degradation of the adhesive strength and peeling problems between the cover plate and the display panel. Accordingly, a structure is needed where moisture or air does not remain on the inner surface of the cover plate.

### SUMMARY

An object of the present disclosure, as for solving the problems described above, is to provide a cover plate having a structure that prevents or suppresses defects from occurring due to moisture or oxygen remaining inside a display device due to a step difference in the print layer.

In particular, another object of the present disclosure is to provide a light emitting display device having a cover plate that prevents or suppresses defects due to steps in the print layer.

To achieve these and other advantages and in accordance with the purpose of the present disclosure, as embodied and broadly described herein, a light emitting display device according to one or more example embodiments the present disclosure includes: a cover panel, an adhesive layer and a display panel. The cover panel includes: a cover plate, a transparent area, a print area, a black pattern and a flattening layer. The cover plate includes a display area and a non-display area surrounding the display area. The transparent area is disposed within the display area of the cover plate. The print area surrounds the transparent area and divides the transparent area from the display area. The black pattern is disposed at the print area on an inner surface of the cover plate. The flattening layer is deposited on entire inner surface of the cover plate as covering the black pattern. The adhesive layer is deposited on the flattening layer. The display panel is attached to the adhesive layer.

In an example embodiment, the adhesive layer is deposited on the flattening layer except the transparent area.

In an example embodiment, the display panel includes: a substrate having the display area and the non-display area; a display element layer on the substrate; an encapsulation layer on the display element layer; a through-hole formed at the substrate, the display element layer and the encapsulation layer, and corresponding to the transparent area; and an internal dam surrounding the through-hole and corresponding to the print area.

In an example embodiment, the display element layer includes: a driving element layer on the substrate; and a light emitting element layer on the driving element layer. The internal dam is surrounding the through-hole and corresponds to the print area in the light emitting element layer.

In an example embodiment, the driving element layer includes: a semiconductor layer on the substrate; a gate insulating layer on the semiconductor layer; a gate electrode on the gate insulating layer and overlapped with the semiconductor layer; an intermediate insulating layer covering the gate electrode; a source electrode connected to one side of the semiconductor layer, and a drain electrode connected to another side of the semiconductor layer, on the intermediate insulating layer; and a planarization layer on the source electrode and the drain electrode. The light emitting element layer includes: a first electrode connected to the drain electrode on the planarization layer; a bank covering circumferences of the first electrode; an emission layer on the bank and the first electrode; and a second electrode on the emission layer.

In an example embodiment, the encapsulation layer includes: a first inorganic layer on the second electrode; an organic layer on the first inorganic layer; and a second inorganic layer on the organic layer. The internal dam includes: the planarization layer; the bank on the planarization layer; and a spacer on the bank. The emission layer, the second electrode and the first inorganic layer are deposited as covering the internal dam. The organic layer is deposited up to a certain height of an inner sidewall of the internal dam. The second inorganic layer covers the internal dam.

In an example embodiment, the light emitting display device further includes a trench surrounding the internal dam and depressed into the display element layer.

In an example embodiment, the trench includes: a hole trench disposed between the internal dam and the through-hole; and an inner trench disposed between the internal dam and pixels adjacent to the through-hole in the display area.

In an example embodiment, the light emitting display device further includes a touch electrode layer between the encapsulation layer and the adhesive layer.

In an example embodiment, the light emitting display device further includes a polarizing plate between the touch electrode layer and the adhesive layer.

The light emitting display device according to example embodiments of the present disclosure may have an advantage of being able to transmit optical information on the front side of the display panel to optical device located on the back side of the display panel by arranging transparent areas next to unit pixels on a portion of the display panel.

Example embodiments of the present disclosure may have a flattening layer to the entire inner surface of a cover plate on which a design layer is printed, so that the inner surface of the cover plate may have a uniform surface condition without step differences. Therefore, air voids caused by the step differences of the design layer may be eliminated, minimized, or reduced. As a result, when attaching the cover plate and the display panel, defects due to step differences may be minimized, reduced or prevented.

In addition to the effects of the present disclosure mentioned above, other features and advantages of the present disclosure are described below or may be clearly understood by those skilled in the art from such descriptions and explanations.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the disclosure.

FIG. 1 is a plan view illustrating a schematic structure of a light emitting display device according to an example embodiment of the present disclosure.

FIG. 2 is a cross-sectional view, along line I-I′ in FIG. 1, illustrating a structure of the light emitting display device according to an example embodiment of the present disclosure.

FIG. 3 is a cross-sectional view illustrating a structure of a cover plate in a light emitting display device according to an example embodiment of the present disclosure.

FIG. 4 is a cross-sectional view illustrating a structure of a cover plate in the light emitting display device according to a comparative example.

FIG. 5 is a cross-sectional view, along line II-II′ in FIG. 1, illustrating a structure of a region where a through-hole is formed in a light emitting display device according to an example embodiment of the present disclosure.

FIG. 6 is an enlarged plan view for illustrating a structure of a region where a through-hole is formed in a light emitting display device according to another example embodiment of the present disclosure.

FIG. 7 is a cross-sectional view, along line III-III′ in FIG. 6, illustrating a structure of a region where a through-hole is formed in a light emitting display device according to another example embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, a protected scope of the present disclosure may be defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an aspect or feature of the present disclosure, a detailed description of such known function of configuration may be omitted.

Reference will now be made in detail to embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, where a detailed description of a function and a configuration known to those skilled in the art are not necessary to understand the example configurations of the present disclosure described herein, such detailed descriptions may be omitted. The terms described in the specification should be understood as follows.

In the present specification, where the terms “comprise,” “have,” “include,” and the like are used, one or more other elements may be added unless a more specific term, such as “only,” is used. An element described in the singular form is intended to include a plurality of elements, and vice versa, unless the context clearly indicates otherwise.

In construing an element, the element is to be construed as including an error or tolerance range even where no explicit description of such an error or tolerance range is provided.

In the description of the various example embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly),” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “under” the second element or “above” the second element in the figure or in an actual configuration, depending on the orientation of the object.

In describing a temporal relationship, where the temporal order is described as, for example, “after,” “subsequent,” “next,” or “before,” a case which is not continuous may be included unless a more limiting term, such as “just,” “immediate(ly),” or “direct(ly),” is used.

It should be understood that, although the terms “first,” “second,” and the like may be used herein to describe various elements, these elements should not be limited by these terms as they are not used to define a particular order. These terms are used only to refer to one element separately from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to refer to one element separately from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other or may be carried out together in a co-dependent relationship.

Hereinafter, examples of a display apparatus according to the present disclosure will be described in detail with reference to the attached drawings. Wherever possible, the same reference numbers will be used throughout the drawings to refer to the same or like parts.

Hereinafter, with reference to the attached figures, the present disclosure will be explained. Since a scale of each of elements shown in the accompanying drawings may be different from an actual scale for convenience of description, the present disclosure is not limited to the scale shown in the drawings.

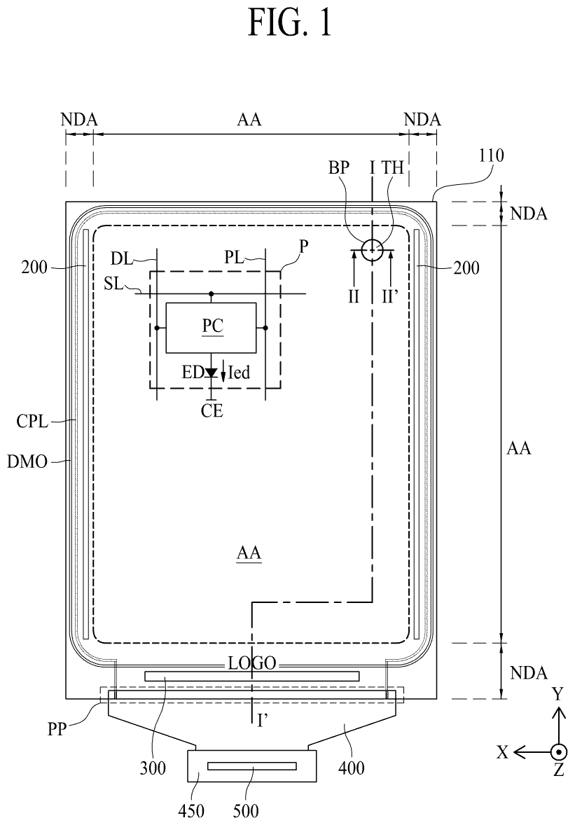

FIG. 1 is a plan view illustrating a schematic structure of a light emitting display device according to an example embodiment of the present disclosure. In FIG. 1, X-axis refers to the direction parallel to the scan line, Y-axis refers to the direction of the data line, and Z-axis refers to the height(or, thickness) direction of the display device.

As shown in FIG. 1, the electroluminescence display comprises a substrate 110, a pixel P, a gate (or scan) driver 200, a source driving IC (Integrated Circuit) 300, a pad portion PP, a through-hole TH, a common power line CPL, an outer dam DMO, a flexible circuit film 400, a circuit board 450, and a timing controller 500. The structure shown in FIG. 1 is only an example, but it is not limited thereto, another configuration may be implemented.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. For an example, the display area AA may have a rectangular shape, a rectangular shape with rounded corners having a predetermined radius of curvature, or a non-rectangular shape with at least six sides. Here, the display area AA having a non-rectangular shape may include at least one protrusion portion or at least one notch portion.

The non-display area NDA, which is an area not representing the video images, may be defined at the circumference areas of the substrate 110 surrounding all or some of the display area AA. The non-display area NDA may be defined as a circumferential area or a bezel area in which video or picture image is not displayed. In the non-display area NDA, the gate driver 200, the source driving IC 300 and the pad portion PP may be formed or disposed.

The gate driver 200 may supply the scan (or gate) signals to the scan lines SL according to the gate control signal received from the timing controller 500. The gate driver 200 may be formed at the non-display area NDA at any one outside of the display area DA on the substrate 110, as a GIP (Gate driver In Panel) type. GIP type means that the gate driver 200 is directly formed on the substrate 110.

The source driving IC 300 may receive the digital video data and the source control signal from the timing controller 500. The source driving IC 300 may convert the digital video data into the analog data voltages according to the source control signal and then supply that to the data lines DL. In FIG. 1, the source driving IC 300 is made as chips and mounted on the substrate 110. However, it is not limited thereto, the source driving IC 300 may be configured as another type.

The flexible circuit film 400 may include a plurality of link lines connecting the pad portion PP to the circuit board 450. The flexible circuit film 400 may be attached on the pad portion PP using an anisotropic conducting film, so that the pad portion PP may be connected to the link lines of the flexible circuit film 400.

The circuit board 450 may be attached to the flexible circuit film 400. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 300, based on the timing signal. The timing controller 500 may supply the gate control signal to the gate driver 200 and supply the source control signal to the source driving IC 300. Depending on the product types, the timing controller 500 may be integrated with the source driving IC 300 into one driving chip and may be mounted on the substrate 110.

The display area AA may include a plurality of scan lines SL (or gate lines), a plurality of data lines DL, a plurality of pixel driving lines PL and a plurality of pixel P. In the display area AA, a plurality of pixels P may be arrayed in a matrix manner. Each pixel P may be defined by a scan line SL, a data line DL and a pixel driving line PL.

The scan lines SL may be extending along a first direction (X-axis direction) and arrayed with a predetermined gap along a second direction (Y-axis direction). The display area AA of the substrate 110 may include a plurality of scan lines SL parallel to the first direction and arrayed with a gap along the second direction. Here, the first direction may be defined as a lateral direction, and the second direction may be defined as a vertical direction of substrate 110.

The data line DL may be extending along the second direction (Y-axis direction) and arrayed with a predetermined gap along the first direction (X-axis). The display area AA of the substrate 110 may include a plurality of data lines DL parallel to the second direction and arrayed with a gap along the first direction.

The pixel driving line PL may be disposed on the substrate 110 as being parallel to the data line DL. However, it is not limited thereto. For another example, the pixel driving current PL may be disposed as being parallel to the scan line SL.

For example, the pixels P may be disposed at the display area AA in a stripe manner. In this case, one unit pixel may include a red sub-pixel, a green sub-pixel and a blue sub-pixel, in addition, one unit pixel may further include a white sub-pixel.

For another example, the pixels P may be disposed at the display area AA in a pentile manner. In this case, one unit pixel may include at least one red sub-pixel, at least two green sub-pixels, and at least one blue sub-pixel arranged in a polygonal shape on a plane. For example, one unit pixel having a pentile structure may have one red sub-pixel, two green sub-pixels, and one blue sub-pixel arranged in a planar octagonal shape. In this case, the blue sub-pixel may have the relatively largest aperture area (or emission area), and the green sub-pixel may have the relatively smallest aperture area.

The pixel P may include a scan line SL and a data line crossing each other, a driving element PC electrically connected to the pixel driving line PL, and a light emitting element ED electrically connected to the driving element PC.

The driving element PC may control the electric current Ied flowing from the pixel driving line PL to the common electrode of the light emitting element ED based on the data voltage supplied from the data line DL in response to the scan signal supplied from the scan line SL.

For example, the driving element PC may include at least two thin film transistors and, and one capacitance. For example, the driving element PC may include a driving thin film transistor supplying a data current Ied to the light emitting diode ED, a switching thin film transistor supplying the data voltage from the data line DL to the driving thin film transistor, and a capacitance storing a gate-source voltage of the driving thin film transistor.

For another example, the driving element PC may include at least three thin film transistors and at least one capacitance. For example, the driving element PC may include a current supply circuit, a data supply circuit and a compensation circuit depending on the operation (or function) of each of at least three thin film transistors. Here, the current supply circuit may include a driving thin film transistor that supplies data current Ied to the light emitting diode ED based on a data voltage. The data supply circuit may include at least one switching thin film transistor that supplies data voltage supplied from a data line DL to the current supply circuit in response to at least one scan signal. The compensation circuit may include at least one compensation thin film transistor that compensates for a change in a characteristic value (threshold voltage and/or mobility) of the driving thin film transistor in response to at least one scan signal.

The light emitting diode ED may emit light with a brightness (or luminance) corresponding to the data current Ied supplied from the driving element PC. In this case, the data current Ied may flow from the pixel driving line PL through the driving thin film transistor DT and the light emitting diode ED to the low-voltage line CPL.

For example, the light emitting diode ED may include a pixel electrode AE (or first electrode or anode electrode) electrically connected to the driving element PC, an emission layer disposed on the pixel electrode AE, and a common electrode CE (or second electrode or cathode electrode) contact the emission layer. The common electrode CE may be connected to the low-voltage line CPL. Even though FIG. 1 does not show the emission layer, a cross-sectional view for explaining a light emitting diode, one example of the light emitting element ED, may illustrate an emission layer.

The common power line CPL may be disposed at the non-display area NDA of the substrate 110, and connected to the common electrode CE disposed at the display area AA. For example, the common power line VSS may be placed at the non-display area NDA surrounding the display area AA along the left side, the upper side and the right side of the substrate 110, excepting the lower side of the substrate 110. One end of the common power line CPL may be disposed at the one portion of the non-display area NDA, and the other end of the common power line VSS may be disposed at the other portion of the non-display area NDA. The middle portion from one end of the common power line CPL to the other end of the common power line VSS may be disposed at the non-display area NDA as surrounding the display area AA. Therefore, the common power line CPL may have an ‘n’ or inverted ‘U’ (or ∩) shape in which the lower side of the non-display area NDA may be opened and other sides are closed in plan view.

The outer dam DMO may be disposed at the non-display area NDA of the substrate 110 to have a closed curve structure surrounding the display area AA. For example, the outer dam DMO may be placed outside the common power line CPL so as to be located at the outermost part on the substrate 110. The pad portion PP and the source driving IC 300 may be disposed out of the outer dam DMO in the non-display area NDA.

Even though FIG. 1 shows that the outer dam DMO is disposed at outermost location on the substrate 110, it is not limited thereto. For another example, the outer dam DMO may be disposed between the commo power line CPL and the gate driver 200. For another example, the outer dam DMO may be disposed between the display area AA and the gate driver 200.

The light emitting display device according to the present disclosure may further include the through-hole TH formed in the display area AA. The through-hole TH may be formed to penetrate only the display panel configuring the display device. For the case in which a through-hole TH is provided to allow lights to pass through, such as a camera hole or a light sensor hole, the through-hole TH may only be formed to penetrate only the display panel but not through the polarization plate or cover plate. For another example in which an accessory penetrating the entire thickness of the display device may be installed, a through-hole TH may be formed to penetrate the display panel and the optical film attached to the upper surface of the display panel, as well as the cover plate.

However, it is not limited thereto, the through-hole TH may be disposed in the non-display area NDA. In this case, since the area of the display area AA may be reduced as area corresponding to not only the area of the through-hole TH but also the circumferences area of the through-hole TH, the area ratio occupied by the display area AA in the display panel may be reduced. The present disclosure may focus on the case where a through-hole TH is placed in the display area AA. Accordingly, the display elements may be not placed only in the area of the through-hole TH within the display area AA, but rather are placed around the through-hole TH, thereby maximizing or increasing the area ratio occupied by the display area AA in the display panel.

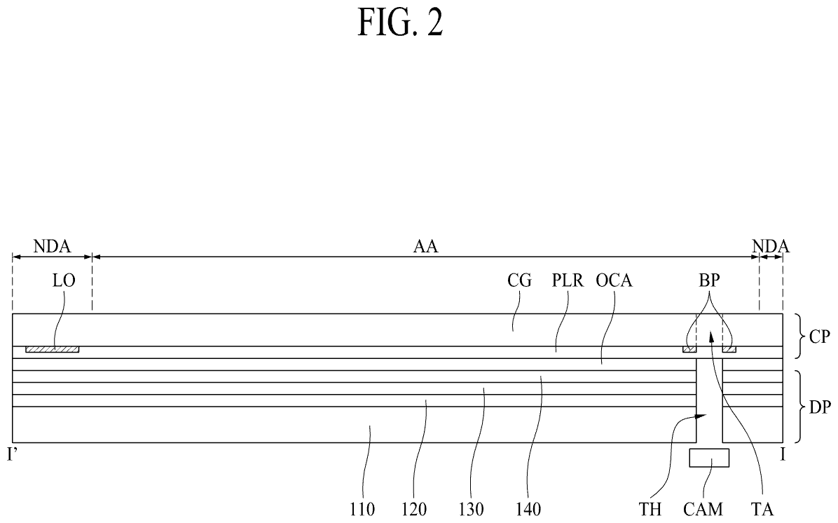

Hereinafter, as shown in FIG. 2, a cross-sectional structure of a light emitting display device according to an example of the present disclosure will be explained. FIG. 2 is an enlarged cross-sectional view, along line I-I′ of FIG. 1, illustrating a structure of a light emitting display device according to an embodiment of the present disclosure.

As shown in FIG. 2, a light emitting display device according to an embodiment of the present disclosure may include a cover plate CP, a display panel DP and an adhesive layer OCA. The display panel DP may be an element having elements for displaying video image data. The cover plate CP may be an element disposed on an upper surface of the display panel DP for protecting the display panel DP. The cover panel CP may include a cover glass CG, a black pattern BP and a flattening layer PLR. The display panel DP may include a substrate 110, a driving element layer 120, a light emitting element layer 130 and an encapsulation layer 140. Here, the driving element layer 120 and the light emitting element layer 130 may be a display element layer. The adhesive layer OCA may be an element for attaching the display panel DP and the cover plate CP. For example, the encapsulation layer 140 of the display panel DP may be attached to the flattening layer PLR of the cover plate CP with the adhesive layer OCA.

The cover glass CG may include a display area DA and a non-display area NDA. The non-display area NDA may surround the display area DA. In FIG. 2 illustrating a cross-sectional view, the non-display area NDA may be disposed at the left side and the right side of the display area DA.

The cover glass CG may have a transparent area TA in the display area AA. On the inner surface of the cover glass CG, a black pattern BP surrounding the transparent area TA may be printed. The area where the black pattern BP is disposed may be called a ‘print area’. The print area may surround the transparent area TA and may divide the display area DA from the transparent area TA.

Further, on inner surface of the cover glass CG, a logo LO for representing the name of company or model name of the product may be printed on the non-display area NDA disposed lower side of the cover glass CG. The logo LO may be printed on the inner surface of the cover glass CG at the printing process of the black pattern BP.

The flattening layer PLR may be deposited on entire inner surface of the cover glass CG on which the black pattern BP and the logo LO are printed. The printed black pattern BP and the logo LO may have a thickness of 20 μm. Therefore, due to the thickness of the printed black pattern BP and the logo LO, the inner surface of the cover glass CG may have a step difference (or level difference). Joining the cover glass CG to the display panel DP with this step difference, a void may be formed where the step difference is formed. Oxygen and/or moisture may remain in the void. When oxygen and moisture intrude into the light emitting element formed on the display panel DP, the light emitting element may be damaged. By applying the flattening layer PLR to the entire inner surface of the cover glass CG, the step difference on the inner surface of the cover glass CG may be removed and the inner surface may be formed smoothly with flattening condition. Further, no void is created in the step portion, and any space where oxygen or moisture remains may be eliminated.

The display panel DP may also include the display area DA and the non-display area NDA. A through-hole TH may be formed at an area in the display area DA, as corresponding to the transparent area TA. The through-hole TH may have a cross-sectional shape in a horizontal plane that is the same size and shape as the transparent area TA.

The through-hole TH may be formed by removing a portion corresponding to a transparent area TA from the substrate 110, the driving element layer 120, the light emitting element layer 130, and the encapsulation layer 140 configuring the display panel DP.

An optical device CAM such as a camera or an infrared detection device may be disposed at the rear surface of the display panel DP. In particular, in some applications, it may be preferable that the light receiving portion of the optical device CAM may be positioned to correspond to the through-hole TH. Optical information incident from the outside of the cover plate CP through the transparent area TA may be provided to the optical device CAM via the through-hole TH.

The through-hole TH may be formed by removing some portions of the substrate 110, the driving element layer 120, the light emitting element layer 130 and the encapsulation layer 140. Therefore, lights entering into the optical device CAM through the through-hole TH may not have any problems such as light quantity reduction or diffraction due to various layers configured in the display panel DP. Accordingly, the display device according to the present disclosure may provide optical information without distortion to the optical device CAM.

Further, at the circumference area of the through-hole TH of the display panel DP, elements other than the display area AA may be placed. For example, an inner dam may be placed to prevent or suppress moisture or oxygen from intruding via the through-hole TH. Due to the elements other than those placed in the display area AA, external light may be reflected or refracted and diffracted, so rainbow patterns may be perceived. To prevent or suppress these problems, a black pattern BP may be printed at the area corresponding to the edge of the through-hole TH, on the inner surface of the cover glass CG.

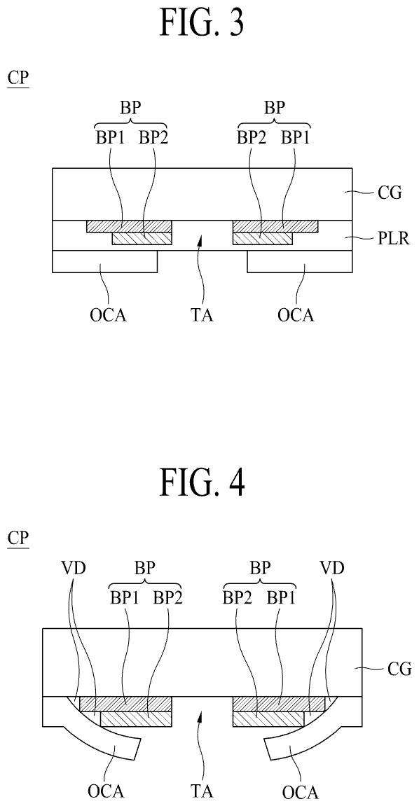

Hereinafter, as shown in FIG. 3, a structure of the inner surface of the cover glass CG according to an embodiment of the present disclosure will be explained. FIG. 3 is a cross-sectional view illustrating a structure of a cover plate in a light emitting display device according to an embodiment of the present disclosure. FIG. 3 illustrates a cross-sectional view enlarging some of the transparent area TA in the cover plate CP.

As shown in FIG. 3, a black pattern BP surrounding the transparent area TA may be printed on the inner surface of the cover glass CG. The black pattern BP may be configured with single printing layer. However, it is not limited thereto, as shown in FIG. 3, the black pattern BP may have a structure in which two printing layers are sequentially stacked.

For example, a first pattern BP1 may be printed on the inner surface of the cover glass CG. The first pattern BP1 may have a closed curve shape with a certain width surrounding the transparent area TA. When the transparent area TA has a circular shape, the first pattern BP1 may have a circular ring shape, or a donut shape.

A second pattern BP2 may be formed on the first pattern BP1. The second pattern BP2 may have smaller size than the first pattern BP1. In particular, in some applications, it may be preferable that an inner circular border of the second pattern BP2 may be arranged as matching to an inner circular border of the first pattern BP1. Further, it may be preferable that an outer circular border of the second pattern BP2 may have smaller diameter than an outer circular border of the second pattern BP2. It may be preferable that the outer circular border may be arranged between the inner circular border of the first pattern BP1 and the outer circular border of the first pattern BP1.

For example, when the size of the second pattern BP2 is larger than that of the first pattern BP1, air or moisture may remain in the gap between the first pattern BP1 and the second pattern BP2. Air and/or moisture may weaken the adhesion between the adhesive layer OCA and the black pattern BP, and then may cause bubbles which may degrade the performance of the adhesive layer OCA.

The thickness of the cover glass CG may be in a range of 0.2 mm to 1.1 mm. Therefore, the inner surface of the cover glass CG where the black pattern BP is printed may have an uneven surface profile due to the black pattern BP. To level the surface condition caused by these step differences, a flattening layer PLR may be applied on the inner surface of the cover glass CG on which a black pattern BP is printed.

The flattening layer PLR may cover entire of the black pattern BP, and may be deposited over entire inner surface of the cover glass CG. In particular, the flattening layer PLR may fill all the step differences formed by the first pattern BP1 and the second pattern BP2, and also may fill all areas of the transparent area TA, so as to have a uniform surface condition without step differences. As a result, the step differences between the black pattern BP and the inner surface of the cover glass CG may be removed (or compensated) by the flattening layer PLR.

The flattening layer PLR may include a resin material for filling (or compensating) the step difference. For example, the flattening layer PLR may be made of an organic material such as acryl resin, epoxy resin, phenolic resin, polyamide resin, urethane resin and polyimide resin. Further, the flattening layer PLR may have a thickness thicker than the black pattern BP. For example, the flattening layer PLR may have a thickness of 30 μm to 100 μm. For another example, when the black pattern BP has a thickness of 5 μm to 10 μm, the flattening layer PLR may have a thickness of 20 μm to 100 μm.

Even though it is not shown in figures, a logo may be printed at the non-display area defined at the lower side of the cover glass CG. The logo, like the black pattern BP, may also cause a step difference with the inner surface of the cover glass CG. However, all step differences may be removed by the flattening layer PLR.

In addition, the black pattern BP or the logo may not be exposed, but be protected by the flattening layer PLR. Therefore, the black pattern BP or the logo may be prevented or protected from being damaged by external force when the cover glass CG is under manufacturing or transporting process.

The adhesive layer OCA may be deposited on the flattening layer PLR. The adhesive layer OCA may include an adhesive material having optically clear feature. The adhesive layer OCA may cover entire surface of the flattening layer PLR. However, it is not limited thereto, as shown in FIG. 3, the adhesive layer OCA may be deposited on the flattening layer PLR except the transparent area TA. For another example, the adhesive layer OCA may be not deposited at the transparent area TA, this case may be to prevent the adhesive layer OCA from being placed in the area corresponding to the through-hole in the display panel that is attached there-under.

Hereinafter, as shown in FIG. 4, the functional feature of the flattening layer PLR according to an embodiment of the present disclosure will be explained. FIG. 4 is a cross-sectional view illustrating a structure of a cover plate in the light emitting display device according to a comparative example. FIG. 4 shows a structure of a cover plate CP according to a comparative example without the flattening layer PLR.

As shown in FIG. 4, the cover plate CP according to a comparative example may include a cover glass CG, a black pattern BP and an adhesive layer OCA. The black pattern BP may be printed at the circular border of the transparent area TA on the inner surface of the cover glass CG. The adhesive layer OCA may be deposited on the inner surface of the cover glass CG at which the black pattern BP is printed.

In particular, the first pattern BP1 may be printed on the inner surface of the cover glass CG. The second pattern BP2 may be printed on the first pattern BP1. The second pattern BP2 may have smaller size than the first pattern BP1. Therefore, a step difference may be formed between the inner surface of the cover glass and the first pattern BP1, further another step difference may be formed between the first pattern BP1 and the second pattern BP2.

With these step differences, the adhesive layer OCA may be deposited thereon. Here, a void VD may be formed between the step difference and the adhesive layer OCA. For example, voids VD may be formed at the outer border of the first pattern BP1 and the outer border of the second pattern BP2. These voids VD may include air and/or moisture. Due to air and/or moisture, the adhesive layer OCA may not be completely adhered to the cover glass CG, which may cause bubble defects. Bubble defects may degrade the performance of the adhesive layer OCA, causing the adhesive layer OCA to peel off from the cover glass CG.

The cover panel CP according to an embodiment of the present disclosure, as shown in FIG. 3, the step differences formed at the border of the printing layer such as the black pattern BP may be filled with the flattening layer PLR, and the final surface condition may be a flat plane status. There is not any void including moisture and/or oxygen. Therefore, there is no problem of the adhesive layer OCA peeling off from the cover glass CG. Further, as the black pattern BP is covered by the flattening layer PLR, it can prevent or protect the cover panel CP from being damaged during the manufacturing process or transporting process.

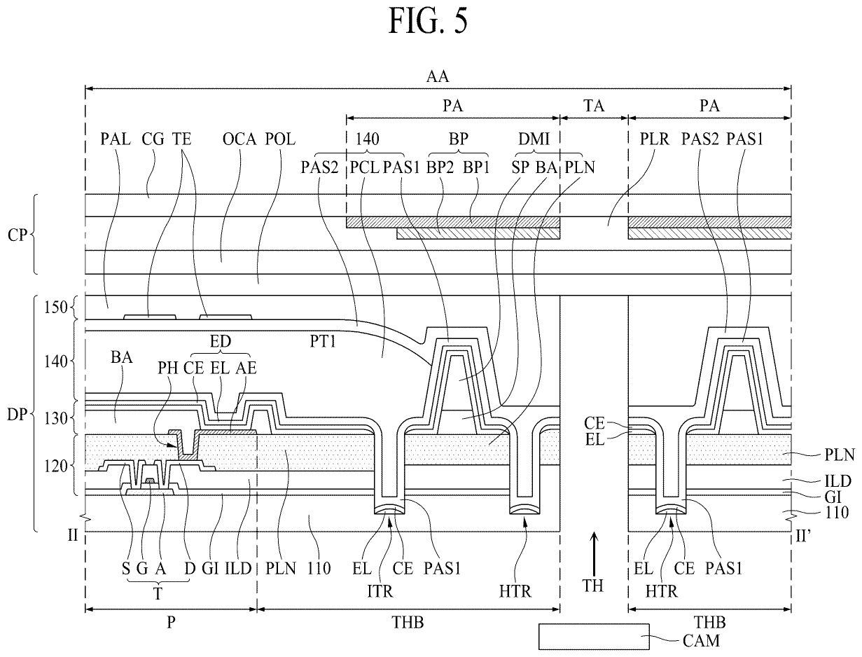

Hereinafter, as shown in FIG. 5, a detailed structure of a light emitting display device according to an embodiment of the present disclosure. In particular, following description may focus on the region where the through-hole and the black pattern are formed. FIG. 5 is a cross-sectional view, along line II-II′ in FIG. 1, illustrating a structure of a region where a through-hole is formed in a light emitting display device according to an embodiment of the present disclosure.

As shown in FIG. 5, a light emitting display device according to the present disclosure may include a cover panel CP and the display panel DP. The cover panel CP and the display panel DP may be attached with an adhesive layer OCA there-between.

The cover panel CP may include a cover glass CG, a black pattern BP and a flattening layer PLR. The cover glass CG may be made of a transparent glass or plastic.

The black pattern BP may be printed on the inner surface of the cover glass CG. The black pattern BP may be printed as surrounding the edge border of the transparent area TA disposed in the display area of the cover glass CG. The black pattern BP and the transparent area TA may be disposed in the display area AA, but any display information may not be represented through the black pattern BP and the transparent area TA. The transparent area TA means the area where lights may pass through. The area where the black pattern BP is printed may block the lights and may not provide any display information, so it may be defined as the printing area PA.

The black pattern BP may include a first pattern BP1 and the second pattern BP2. The first pattern BP1 may be directly printed on the inner surface of the cover glass CG. The second pattern BP2 may be printed on the first pattern BP1. Additionally, a third pattern may be further printed. The second pattern BP2 may have a size smaller than the first pattern BP1.

The transparent area TA may have a circle shape, a regular hexagonal shape, a regular octagonal shape or oval shape. When the transparent area TA has a circular shape, the first pattern BP1 and the second pattern BP2 may have a hollow disc shape surrounding the transparent area TA. The first pattern BP1 and the second pattern BP2 may be arranged concentrically. The inner circle of the first pattern BP1 and the inner circle of the second pattern BP2 may be arranged to match each other. The outer circle of the second pattern BP2 may be arranged at a certain distance from the outer circle of the first pattern BP1 in the center direction. However, it is not limited thereto, the outer circle of the second pattern BP2 may be arranged to match the outer circle of the first pattern BP1, and the inner circle of the second pattern BP2 may be arranged at a certain distance outward from the inner circle of the first pattern BP1.

A flattening layer PLR may be deposited on the black pattern BP and the inner surface of the cover glass CG. The flattening layer PLR may be deposited as covering entire inner surface of the cover glass CG. The flattening layer PLR may completely cover the black pattern BP. Therefore, the flattening layer PLR may fill the step difference at the edge of the black pattern BP, thereby flattening the step difference. Further, the flattening layer PLR may be deposited with a thickness thicker than the black pattern BP at the transparent area TA. With the flattening layer PLR, the inner surface of the cover glass CG may maintain an even and flattened condition.

The adhesive layer OCA may be deposited on the flattening layer PLR. The adhesive layer OCA may be deposited as covering entire surface of the flattening layer PLR. That is, the adhesive layer OCA may cover entire inner surface of the cover glass CG. However, it is not limited thereto, as shown in FIG. 2, the adhesive layer OCA may not be deposited at the transparent area TA.

The display panel DP may be attached at the adhesive layer OCA. The display panel DP may include a substrate 110, a driving element layer 120, a light emitting element layer 130, an encapsulation layer 140, a touch sensor layer 150, and a polarization layer POL.

A buffer layer (not shown) may be deposited on the upper surface of the substrate 110. The buffer layer may be deposited on one surface of the substrate 110 to block moisture from intruding into the driving element layer 120 and the light emitting element layer 130 which is vulnerable to moisture intrusion. For example, the buffer layer may include a plurality of inorganic layers alternately stacked. For example, the buffer layer may be formed as a multi-layer in which one or more inorganic layers of a silicon oxide layer SiOx, a silicon nitride layer SiNx and a silicon oxynitride layer SiON are alternately stacked. In some cases, the buffer layer may not be included.

The driving element layer 120 may include a thin film transistor T. The thin film transistor T may be formed at each of a plurality of pixels P disposed in the display area AA, and a gate driving circuit 200 disposed in the non-display area NDA.

For example, the driving element layer 120 may include a semiconductor layer A, a gate insulating layer GI, a gate electrode G, an intermediate insulating layer ILD, a source electrode S, a drain electrode D and a planarization layer PLN. In FIG. 2, the thin film transistor T may have a top gate structure in which the gate electrode G is disposed on the semiconductor layer A. However, it is not limited thereto. For another example, the thin film transistor T may have a bottom gate structure in which the gate electrode G is disposed under the semiconductor layer S, or a double gate structure in which two gate electrodes G are disposed on and under the semiconductor layer A, respectively.

The semiconductor layer A may be formed on the substrate 110 or the buffer layer. The semiconductor layer A may include a silicon semiconductor material, an oxide semiconductor material or an organic semiconductor material. The semiconductor layer A may have a single layer structure or a multiple layer structure. A light shielding layer may be further disposed between the substrate 110 and the semiconductor layer A, to block external lights from the outside into the semiconductor layer A.

The gate insulating layer GI may be deposited over entire surface of the substrate 110 to cover the semiconductor layer A. The gate insulating layer GI may be made of an inorganic material such as silicon oxide SiOx or silicon nitride SiNx, or a multiple layer thereof.

The gate electrode G may be formed on the gate insulating layer GI as overlapped with the semiconductor layer A. The gate electrode G may be formed with a scan line SL. For example, the gate electrode G may be formed as a single layer or multiple layer made of one or an alloy of molybdenum (Mo), aluminum (Al), chromium (Cr), gold (Au), titanium (Ti), nickel (Ni), neodymium (Nd) and copper (Cu).

The intermediate insulating layer ILD may be deposited on entire surface of the substrate 110 as covering the gate electrode G and the gate insulating layer GI. The intermediate insulating layer ILD may provide a flattened surface on the gate electrode G and the gate insulating layer GI.

The source electrode S and the drain electrode D may be formed on the intermediate insulating layer ILD so as to overlap with the semiconductor layer A and to face each other with the gate electrode G interposed there-between. The source electrode S and the drain electrode D may be formed with the data line DL and the pixel driving line PL. That is, the source electrode S, the drain electrode D, the data line DL and the pixel driving line PL may be formed simultaneously by a patterning process for the source-drain material.

Each of the source electrode S and the drain electrode D may connect to the semiconductor layer A via contact holes penetrating the intermediate insulating layer ILD and the gate insulating layer GI. The source electrode S and the drain electrode D may be formed as a single layer or multiple layers made of one or an alloy of molybdenum (Mo), aluminum (Al), chromium (Cr), gold (Au), titanium (Ti), nickel (Ni), neodymium (Nd) and copper (Cu). Here, the source electrode S of the thin film transistor T shown in FIG. 2 may be electrically connected to the pixel driving line PL.

The thin film transistor T disposed in the pixel P of the substrate 110 may be used to configure the driving element PC. Further, the gate driving circuit 200 disposed in the non-display area NDA of the substrate 110 may include a transistor that is identical to or similar to the thin film transistor T provided in the pixel P. In FIG. 5, even though only one thin film transistor T is drawn, the thin film transistor T may include a switching thin film transistor, a driving thin film transistor and/or a compensating thin film transistor.

The planarization layer PLN may be deposited on entire surface of the substrate 110 to cover the thin film transistor T. The surface of the substrate 110 on which the thin film transistor T is not even, so the planarization layer PLN may be a layer for making the surface condition be flattened. To equalize the height difference caused by the uneven surface condition, the planarization layer PLN may be formed of an organic material. For example, the planarization layer PLN may be made of an organic material such as acryl resin, epoxy resin, phenolic resin, polyamide resin or polyimide resin. A pixel contact hole PH exposing some of the drain electrode D may be formed at the planarization layer PLN.

The light emitting element layer 130 may include a light emitting diode OLE. The light emitting diode OLE may include a first electrode AE (or anode electrode or pixel electrode), an emission layer EL and a second electrode CE (or cathode electrode or common electrode). The light emitting diode OLE may display video image by emitting lights in accordance with the current controlled by the thin film transistor T. The first electrode AC of the light emitting diode OLE may be connected to the drain electrode D of the thin film transistor T, the second electrode CE may be connected to a low-power line (not shown) supplied with a low-power voltage. That is, the light emitting diode OLE may be driven by the current controlled by the thin film transistor T and flowing from the pixel power line PL to the low-power line.

The first electrode AE may be formed on the upper surface of the planarization layer PLN. The first electrode AE may be connected to the drain electrode D of the thin film transistor T via the pixel contact hole PH. The first electrode AE may have different structure depending on the emission type of the light emitting diode OLE. For the case of the bottom emission type in which the light is provided to the substrate 110, the first electrode AE may be made of a transparent conductive material. For the case of top emission type in which the light is provide upward from the emission layer, the first electrode AE may be made of a metal material having excellent light reflectivity.

A bank BA may be formed on the first electrode AE. The bank BA may cover the circumferences of the first electrode AE, and expose most central portions of the first electrode AE. The portions of the first electrode AE exposed from the bank BA may be defined as the emission area. The area except the emission area in one pixel P may be defined as non-emission area. The bank BA may be disposed as covering the non-emission area.

An emission layer EL may be deposited on the substrate 110 having the bank BA and the first electrode AE. The emission layer EL may be deposited on entire of the display area AA of the substrate 110 as covering the first electrode AE and the bank BA.

The second electrode CE may be deposited on the emission layer EL. The second electrode CE may be made one sheet layer covering entire surface of the substrate 110 including all of the plurality of pixel P. For example, the second electrode CE may have a sheet shape stacked on entire surface of the display area AA. In some cases, the second electrode CE may be extended to cover some non-display area NDA after covering entire of the display area AA.

A spacer SP may be formed on the bank BA. The spacer SP may be distributed and arranged in the non-emission area within the display area AA where the light emitting element ED is not disposed. The spacer SP may be an element for preventing or suppressing the screen mask from making direct contact with the substrate 110, during the process of depositing the emission layer EL. The spacer SP may be disposed on the bank BA, and the emission layer EL and the second electrode CE may be deposited as passing over the spacer SP placed within the display area AA.

In some cases, the emission layer EL and/or the second electrode CE may not pass over the spacer SP. As the spacer SP is disposed on some of the bank BA within the display area AA, even though the second electrode CE does not pass over the spacer SP, the second electrode CE may have a structure that may be connected and cover the entire display area AA.

An encapsulation layer 140 may be deposited on the light emitting element layer 130. For example, the encapsulation layer 140 may include a first inorganic layer PAS1, an organic layer PCL on the first inorganic layer PAS1, and a second inorganic layer PAS2 on the organic layer PCL. The first inorganic layer PAS1 and the second inorganic layer PAS2 may play role of blocking the intrusion of moisture and oxygen. For example, the first inorganic layer PAS1 and the second inorganic layer PAS2 may be made of an inorganic material such as silicon nitride, aluminum nitride, zirconium nitride, titanium nitride, hafnium nitride, tantalum nitride, silicon oxide, aluminum oxide or titanium oxide, etc. The first inorganic layer PAS1 and the second inorganic layer PAS2 may be deposited by the chemical vapor deposition process or the atomic layer deposition process.

The organic layer PCL may be sandwiched and surrounded by the first inorganic layer PAS1 and the second inorganic layer PAS2. The organic layer PCL may be formed to a relatively thick thickness compared to the first inorganic layer PAS1 and/or the second inorganic layer PAS2 so as to be able to absorb and/or capture foreign particles that may be generated during the manufacturing process. The organic layer PCL may be made of an organic material such as silicon oxycarbon SiOCz acrylic material or epoxy resin material. The organic layer PCL may be formed by the coating process, for example, an inkjet coating process or a slit coating process.

A light emitting display device according to an embodiment of the present disclosure may further include a dam structure. The dam structure may include an external dam DMO (shown in FIG. 1) disposed outside of the display area AA, and an internal dam DMI disposed inside of the display area AA. The external dam DMO may be disposed at the non-display area NDA of the substrate 110 to prevent or suppress the organic layer PCL from overflowing. The internal dam DM1 may surround the through-hole TH inside the display area AA. The external dam DMO may have the same structure as the internal dam DMI, except that the location of the placement is different, so a detailed description for the external dam DMI will not be duplicated.

The dam structure, including the internal dam DMI and the external dam DMO, may have a triple layer structure formed perpendicular to the substrate 110. For example, the dam structure may include a first layer formed of the planarization layer PLN, a second layer formed of the bank BA and a third layer formed of the space SP.

The first layer may have a trapezoidal cross-sectional structure by patterning the planarization layer PLN. The second layer may have another trapezoidal cross-sectional structure that is stacked on top of the first layer. The third layer may have still another trapezoidal cross-sectional structure that is stacked on top of the second layer. For a case in which the thickness of the organic layer PCL is thin and it is easy to control the spreadability of the organic layer PCL, the internal dam DMI may have not so high thickness. In this case, the third layer may be omitted from the dam structure.

The dam structure, i.e., the internal dam DMI shown in FIG. 5, may be covered by the first inorganic layer PAS2 and/or the second inorganic layer PAS2. The organic layer PCL may contact some of the inner sidewall of the internal dam DMI. For example, the height of the organic layer PCL, at the end edge, from the bottom to the top surface may be higher than the first layer of the internal dam DMI, and lower than the second layer of the internal dam DMI. Otherwise, the height of the organic layer PCL from the bottom to the top surface may be higher than the second layer of the internal dam DMI, and lower than the third layer of the internal dam DMI.

It may be preferable that the height of the organic layer PCL, at the end edge, from the bottom to the top surface may be lower than the entire height of the internal dam DMI. As a result, the first inorganic layer PAS1 and the second inorganic layer PAS2 may be in surface contact with each other at the upper surface and outer sidewall of the inner dam DMI.

The touch sensor layer 150 may be stacked on the encapsulation layer 140. The touch sensor layer 150 is an element for detecting when a user touches a specific location in the display area AA using a finger or a touch pen. For example, the touch sensor layer 150 may include a plurality of touch electrodes TE and a cover layer PAL. One touch electrode TE may be arranged in the plurality of pixels P. Otherwise, one touch electrode TE may be arranged at one pixel P. The touch electrode TE may be configured in a single layer or multiple layers. In FIG. 2, a single-layer structure is depicted for convenience. The cover layer PAL may be deposited on the touch electrodes TE for covering all touch electrodes TE.

The polarizing plate POL may be attached on the touch sensor layer 150. The polarizing plate POL may have a phase delay feature to prevent or suppress external light from being reflected.

The cover plate CP may be attached on the polarizing plate POL. For example, the cover plate CP and the polarizing plate POL may be attached with the adhesive layer OCA.

Hereinafter, the through-hoe TH in the light emitting display device according to the present disclosure will be described in detail. The through-hole TH may accommodate optical devices CAM such as a camera or an optical sensor. Since the driving element PC and the light emitting element ED may be placed in the display area AA, when a camera or optical sensor is placed below them, light incident on the camera or the optical sensor may not be properly provided. Therefore, when a camera or an optical device is located within the display area AA, it may be preferable that a through-hole TH may be formed by removing the driving element PC and the light emitting element ED.

The through-hole TH may be formed by removing the substrate 110 at the most bottom layer and the driving element layer 120, the light emitting element layer 130, the encapsulation layer 140 and the touch sensor layer 150 stacked on the substrate 110. The polarizing plate POL stacked on the touch sensor layer 150 may be left without being removed to form the through-hole TH. However, in some cases, the polarizing plate POL may be removed to form the through-hole TH.

Around the through-hole TH, a plurality of pixels P may be disposed. The area between the pixel P closest to the through-hole TH among the pixels P and the through-hole TH may be defined as a hole boundary THB. The hole boundary THB may be overlapped with the print area PA defined at the cover plate CP. The hole boundary THB and the print area PA may have the same area. However, it is not limited thereto, any one of the hole boundary THB and the print area PA may be larger than the other.

In the light emitting display device having the through-hole TH, the sidewall of the through-hole TH may be exposed to air. When the light emitting element ED has an organic material, moisture and/or foreign material may be intruded into the display area AA through the organic material exposed to air. As a result, the light emitting element ED may be damaged so the function of the display device may be degraded.

To prevent or suppress the above-mentioned problem, the internal dam DMI may be formed around the through-hole TH. The internal dam DMI may be a structural element for preventing or suppressing moisture from spreading into the display area AA even though moisture intrudes via the sidewall of the through-hole TH. For example, the internal dam DMI may be disposed between the through-hole TH and the pixel P surrounding the internal dam DMI, in the display area AA. The internal dam DMI may have a closed curved shape surrounding the through-hole TH as corresponding to the shape of the through-hole TH. To maximize or increase the displaying size ratio of the display area AA, it may be preferable to place the internal dam DMI closest to the through-hole TH. In this case, the internal dam DMI alone may not prevent moisture intrusion, diffusion and propagation.

To compensate the function of the internal dam DMI, a trench may be disposed around the internal dam DMI. For example, a hole-trench HTR may be formed between the internal dam DMI and the through-hole TH. Further, an inner trench ITR may be formed between the internal dam DMI and the pixel P closest to the through-hole TH. The hole-trench HTR and the inner trench ITR may have the same or at least very similar structure.

The inner trench ITR may have a closed curve shape surrounding the internal dam DMI as corresponding to the shape of the internal dam DMI. The hole-trench HTR may have a closed curve shape surrounding the inner side oof the internal dam DMI as corresponding to the shape of the internal dam DMI. Therefore, the internal dam DMI, the inner trench ITR and the hole-trench HTR may have different closed curve shapes. However, it is not limited thereto, they may also have closed curve shapes of the same shape but different sizes.

These trenches may have a well shapes that are depressed from the upper surface of the planarization layer PLN into a certain depth in the substrate 110. With this structure, the emission layer EL may be deposited only on the upper surface of the planarization layer PLN and the bottom surface of the trenches, but may be not deposited to the sidewall of the trenches, so that the connectivity of the emission layer EL may be broken. Therefore, the emission layer EL containing the organic material may be disconnected from the outside around the internal dam DMI, thereby preventing or suppressing moisture from propagating into the display area AA along the emission layer EL.

To ensure that structures such as the internal dam DMI, the hole-trench HTR and the inner trench ITR arranged around the through-hole TH are not recognized from the outside, a black pattern BP may be arranged to surround the through-hole TH on the inner surface of the cover glass CG. The black pattern BP may be an element to prevent or suppress external light from being reflected by metal materials placed at the hole-boundary THB between the through-hole TH and the adjacent pixel P and be perceived by the user. The black pattern BP may be an organic material containing a black dye or pigment with excellent light absorption property.

It may be preferable that the black pattern BP formed at the cover plate CP may be arranged to overlap with the internal dam DMI, the hole-trench HTR and the inner trench ITR formed on the display panel DP. For example, it may be preferable to define the black pattern BP formed in the print area PA to overlap the internal dam DMI, the hole trench HTR and the inner trench ITR, even though the hole boundary THB has a larger area than the print area PA.

The light emitting display device shown in FIG. 5 may have a structure in which the adhesive OCA of the cover plate CP may be attached to the polarizing plate POL of the display panel DP. FIG. 5 shows a case in which the polarizing plate POL have not open area corresponding to the through-hole TH. In this case, the adhesive layer OCA may be deposited on entire surface of the flattening layer PLR.

For another example, the polarizing plate POL may have a structure in which the portion corresponding to the through-hole TH may be removed. Since the polarizing plate POL may reduce the amount of lights transmitted by half, when the polarizing plate POL is placed at the through-hole TH, the amount of lights incident into the optical device CAM may be reduced, so that the optical device CAM may not properly operate. To prevent or suppress this problem, the polarizing plate POL may have a structure in which the portion corresponding to the through-hole TH may be removed.

For this case, it may be preferable that the adhesive layer OCA may not be deposited at the transparent area TA of the cover plate CG corresponding to the through-hole TH. As a result, only the flattening layer PLR and the cover glass CG may remain at the transparent area TA having the through-hole TH. With this structure, the amount of lights provided to the optical device CAM through the transparent area TA and the through-hole TH may be maximized or increased.

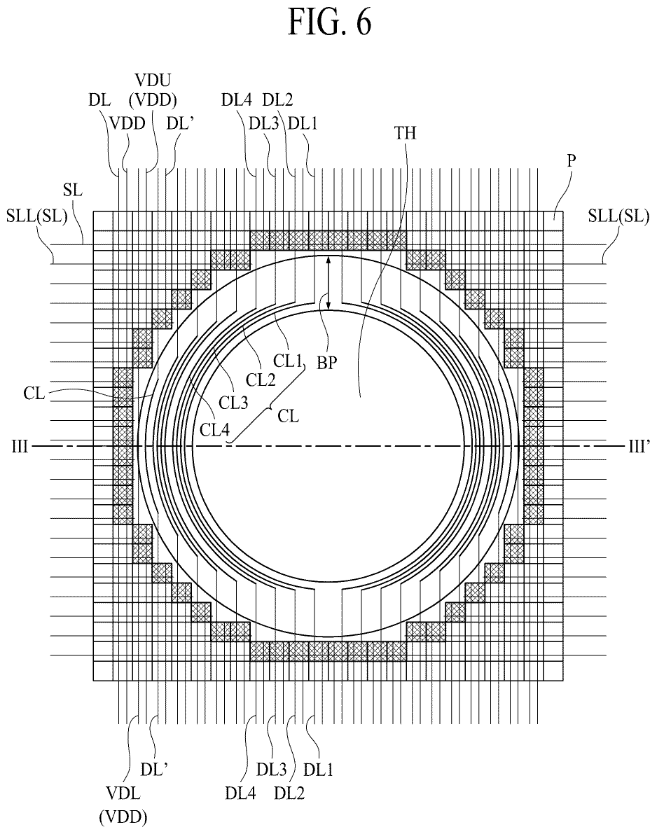

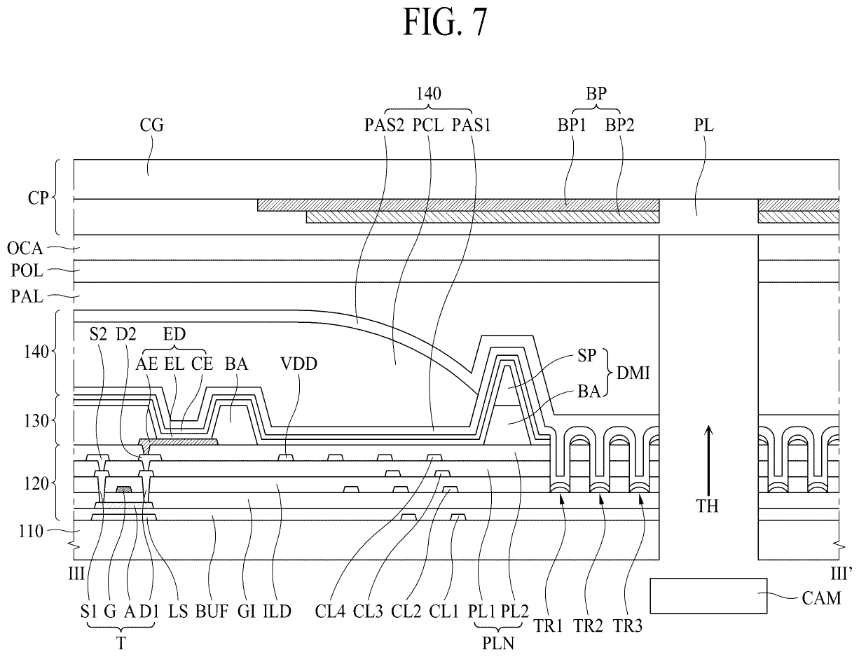

Hereinafter, as shown in FIGS. 6 and 7, a light emitting display device according to another example embodiment of the present disclosure will be explained. FIG. 6 is an enlarged plan view for illustrating a structure of a region where a through-hole is formed in a light emitting display device according to another example embodiment of the present disclosure.

As shown in FIG. 6, a plurality of pixels P may be arrayed in a matrix manner. Each pixel P may have a scan line SL, a data line DL and a driving current line VDD. For example, one scan line SL may be arranged per pixel row. The scan line SL may run horizontally or along X-axis. Each pixel column may have one data line DL and one driving current line VDD. The data line DL and the driving current line VDD may run vertically or along Y-axis.

The through-hole TH may be an area where lines including the scan line SL, the data line DL and the driving current line VDD are not pass through. That is, to maintain the through-hole TH in a transparent state, it may be preferable that lines made of metal materials may be not arranged to pass through the through-hole TH.

As shown in FIG. 6, the pixels P disposed where the through-hole TH is not formed may share one scan line SL. On the other hand, the pixels P arranged in the through-hole TH may be, respectively, connected to the scan lines SL separated based on the through-hole TH. For example, pixels P arranged at the left side of the through-hole TH may share the left scan line SLL, and pixels P arranged at the right side of the through-hole TH may share the right scan line SLR.

In addition, the pixels P disposed where the through-hole TH is not formed may share one driving current line VDD. On the other hand, the pixels P arranged in the through-hole TH may be, respectively, connected to the driving current lines VDD separated based on the through-hole TH. For example, pixels P arranged at the upper side of the through-hole TH may share the upper driving current line VDU, and pixels P arranged at the lower side of the through-hole TH may share the lower driving current line VDL.

Further, the pixels P disposed at pixel column arranged where the through-hole TH is not formed may share one data line DL. Pixels P disposed in the through-hole TH may share one data line DL′. In particular, the data line DL′ passing the through-hole TH may be connected to a connection line CL configured to make a detour the through-hole TH.

The structure of the connection line CL will be explained in detail. For example, a first data line DL1 may be assigned (or, allocated) to the pixels P that are arranged most adjacent to the left side from the center line of the through-hole TH. The first data line DL1 may have a first connection line CL1 that bypasses (or, detour) the through-hole TH. Further, a second data line DL2 may be assigned to the pixels P that are arranged second adjacent to the left side from the center line of the through-hole TH. The second data line DL2 may have a second connection line CL2 that bypasses the through-hole TH.

In the same way, a third data line DL3 may be assigned to the pixels P that are arranged third adjacent to the left side from the center line of the through-hole TH. The third data line DL3 may have a third connection line CL3 that bypasses the through-hole TH. A fourth data line DL4 may be assigned to the pixels P that are arranged fourth adjacent to the left side from the center line of the through-hole TH. The fourth data line DL4 may have a fourth connection line CL4 that bypasses the through-hole TH.

The connection lines CL including the first connection line CL1 to the fourth connection line CL4 may be disposed on the same layer. However, it may be preferable that the connection lines CL may be disposed as overlapped with the black pattern BP surrounding the through-hole TH. The connection lines CL may include metal materials, so light incident from outside may be reflected by the connection line CL and obstruct the user's view. It may be preferable to block the reflected light with a black pattern BP.

When the number of the connection lines CL increases and the connection lines CL are arranged on the same layer, it may be difficult to arrange all the connection lines CL within the area of the black pattern BP. For this case, by arranging the connection lines CL on different layers and forming them to overlap each other, all the connection lines CL may be arranged within the area of the black pattern BP.

As shown in FIG. 7, a structure for arranging the connection lines CL within an area of the black pattern BP will be explained in detail. FIG. 7 is a cross-sectional view, along line III-III′ in FIG. 6, illustrating a structure of a region where a through-hole is formed in a light emitting display device according to another example embodiment of the present disclosure.

As shown in FIG. 7, a light emitting display device according to another example embodiment of the present disclosure may include a substrate 110, a driving element layer 120, a light emitting element layer 130, an encapsulation layer 140, a polarizing layer POL and a cover plate CP. The cover plate CP may be attached on the polarizing plate POL with an adhesive layer OCA made of an optical clear adhesive material.

A buffer layer BUF may be deposited on the substrate 110. A light shielding layer LS may be disposed between the substrate 110 and the buffer layer BUF.

A semiconductor layer A may be formed on the buffer layer BUF. A gate insulating layer GI may be deposited on the semiconductor layer A. A gate electrode G may be formed on the gate insulating layer. The gate electrode G may be overlapped with the semiconductor layer A. An intermediate insulating layer ILD may be deposited on the gate electrode G.

A first source electrode S1 and a first drain electrode D1 may be formed on the intermediate insulating layer ILD. The first source electrode S1 may be connected to one side of the semiconductor layer A. The first drain electrode D1 may be connected to another side of the semiconductor layer A. A first planarization layer PL1 may be deposited on the first source electrode S1 and the first drain electrode D1.

A second source electrode S2 and a second drain electrode D2 may be formed on the first planarization layer PL1. The second source electrode S2 may be connected to the first source electrode S1, and the second drain electrode D2 may be connected to the first drain electrode D1.

A second planarization layer PL2 may be deposited on the second source electrode S2 and the second drain electrode D2. The first planarization layer PL1 and the second planarization layer PL2 may be collectively referred to as a planarization layer PL. However, it is not limited there to, one planarization layer may be deposited. The layers from the buffer layer BUF to the planarization layer PL may be defined as the driving element layer 120.

A first electrode AE may be formed on the second planarization layer PL2. A bank BA may be formed as covering the circumferences of the first electrode AE and exposing the central portions of the first electrode AT. The bank BA may be formed along the border of the through-hole TH. Further, a spacer SP may be stacked on the bank BA formed around the through-hole TH to form an internal dam DMI.

An emission layer EL may be deposited on the bank BA and the first electrode AE. A second electrode CE may be deposited on the emission layer EL. The layers from the first electrode AE to the second electrode CE may be defined as the light emitting element layer 130.

An encapsulation layer 140 may be deposited on the emission layer EL. The encapsulation layer 140 may include a first inorganic layer PAS1, an organic layer PCL and a second inorganic layer PAS2 stacked sequentially. A cover layer PAL may be stacked on the encapsulation layer 140.

A trench may be formed between the internal dam DMI and the through-hole TH. For example, the trench may include a first trench TR1, a second trench TR2 and a third trench TR3. These trenches may be formed by patterning the second planarization layer PL2, the first planarization layer PL1 and the intermediate insulating layer ILD, sequentially. On the bottom surface of the trenches, the emission layer EL and the second electrode CE may be deposited. Further, the first inorganic layer PAS1 of the encapsulation layer 140 may be stacked in the trenches. Further, the second inorganic layer PAS2 may fill the trenches.

The internal dam DMI may have a feature of preventing or suppressing the organic layer PCL of the encapsulation layer 140 from overflowing toward the through-hole TH. For example, the organic layer PCL may be stacked up to a portion of the height of the inner sidewall of the internal dam DMI. On the contrary, the second inorganic layer PAS2 may be deposited on the organic layer PCL and extend beyond the internal dam DMI to the through-hole TH.

The through-hole TH may be formed by removing (or patterning) the substrate 110, the driving element layer 120, the light emitting element layer 130, the encapsulation layer 140 and the cover layer PAL. Further, the polarizing plate POL may be patterned so as to be removed a portion corresponding to the through-hole TH.

The cover plate CP may be attached on the polarizing layer POL. For example, the cover plate CP and the polarizing plate POL may be attached with the adhesive layer OCA.

The cover plate CP may include a cover glass CG, a black pattern BP and a flattening layer PLR. The cover glass CG may be made of a transparent glass or a transparent plastic material.

The black pattern BP may be printed on the inner surface of the cover glass CG. The black pattern BP may be disposed as surrounding the transparent area TA defined in the display area AA of the cover glass CG. The black pattern BP and the transparent area TA may be disposed in the display area AA, but video information does not be displayed thereon. The transparent area TA means an area passing lights. The area where the black pattern BP surrounding the transparent area TA is formed may block the light, and may not provide display information, so this area may be defined as the print area PA.

The black pattern BP may include a first pattern BP1 and a second pattern BP2. The first pattern BP1 may be directly printed on the inner surface of the cover glass CG. The second pattern BP2 may be printed on the first pattern BP1. In addition, a third pattern may be included. The second pattern BP2 may have a size smaller than the first pattern BP1.

The flattening layer PLR may be deposited on the black pattern BP and the inner surface of the cover glass CG. The flattening layer PLR may cover entire inner surface of the cover glass CG. The flattening layer PLR may completely cover the black pattern BP. Therefore, the flattening layer PLR may fill and eliminate the step difference formed at the edge of the black pattern BP. Further, the flattening layer PLR may have a thickness thicker than the black pattern BP in the transparent area TA. Due to the flattening layer PLR, the inner surface of the cover glass CG may be maintained in an even flat condition.

The adhesive layer OCA may be deposited on the flattening layer PLR. The adhesive layer OCA may cover entire surface of the flattening layer PLR. For example, the adhesive layer OCA may be deposited on the inner surface of the cover glass CG except the area corresponding to the through-hole TH.

The structure of lines disposed around the through-hole TH according to another embodiment of the present disclosure will be explained. As shown in FIGS. 6 and 7, connecting lines CL may be arranged to connect the data line DL detouring around the through-hole TH. In particular, the connecting lines CL may be covered by the black pattern BP overlapping with the area around the through-hole TH.

To reduce the area occupied by the connecting lines CL, that is, to dispose the connecting lines CL within the area occupied by the black pattern BP, the connecting lines CL may have a structure in which they are formed in different layers and overlapped each other.

For example, the first connecting line CL1 connected to the first data line DL1 arranged to the pixels P disposed most adjacent to the left side from the center line of the through-hole TH may be formed on the same layer as the light shielding layer LS. Meanwhile, a second connecting line CL2 connected to the second data line DL2 arranged to the pixels disposed second adjacent to the left side from the center line of the through-hole TH may be formed at the same layer as the gate electrode G.

A third connecting line CL3 connected to the third data line DL3 arranged to the pixels disposed third adjacent to the left side from the center line of the through-hole TH may be formed at the same layer as the first source electrode S1. Meanwhile, a fourth connecting line CL4 connected to the fourth data line DL4 arranged to the pixels disposed fourth adjacent to the left side from the center line of the through-hole TH may be formed at the same layer as the second source electrode S2.

By forming at the different layers with insulating layers there-between, the first connecting layer CL1, the second connecting layer CL2, the third connecting layer CL3 and the fourth connecting layer CL4 may be arranged to overlap each other. Therefore, many connection lines may be placed within the area of the black pattern BP having a narrow area. The scan line SL formed on the same layer as the gate electrode A may not be arranged as detouring around the through-hole TH. Therefore, the connecting line CL detouring around the through-hole TH may be formed on the layer where the scan line SL is formed. In addition, a connecting line CL may be formed on the layer where the light shielding layer LS is formed.

For convenience of explanation, the connecting line CL including a first connecting layer CL1, a second connecting line CL2, a third connecting line CL3 and a fourth connecting line CL4 is used as an example. As shown in FIGS. 6 and 7, more connecting lines may be placed within the black pattern BP.

According to another embodiment of the present disclosure, the connecting lines CL, the internal dam DMI and the trenches TR1, TR2 and TR3 are disposed as overlapped with the black pattern BP. Therefore, the black pattern BP may prevent or suppress external light from being reflected by these elements.

In addition, the black pattern BP on the cover plate CP may be completely covered by the flattening layer PLR, so that the inner surface of the cover panel CP may have even flat surface condition. Therefore, no bubble phenomenon occurs on the edge of the black pattern BP, and thus no damage due to bubbles occurs.

Furthermore, the though-hole TH in which the optical device CAM is placed may have a structure in which only a cover glass CG and a flattening layer PLR are remained. As a result, the amount of lights provided to the optical device CAM via the through-hole TH may be maximized or increased.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device, comprising:
a cover panel including:
a cover plate including a display area and a non-display area surrounding the display area;
a transparent area disposed within the display area of the cover plate;
a print area surrounding the transparent area and dividing the transparent area from the display area;
a black pattern disposed at the print area on an inner surface of the cover plate; and
a flattening layer deposited on entire inner surface of the cover plate as covering the black pattern;
an adhesive layer deposited on the flattening layer; and
a display panel attached to the adhesive layer.

2. The light emitting display device according to claim 1, wherein the adhesive layer is deposited on the flattening layer except the transparent area.

3. The light emitting display device according to claim 1, wherein the display panel includes:
a substrate having the display area and the non-display area;
a display element layer on the substrate;
an encapsulation layer on the display element layer;
a through-hole formed at the substrate, the display element layer and the encapsulation layer, and corresponding to the transparent area; and
an internal dam surrounding the through-hole and corresponding to the print area.

4. The light emitting display device according to claim 3, wherein the display element layer includes:
a driving element layer on the substrate; and
a light emitting element layer on the driving element layer, and
wherein the internal dam is surrounding the through-hole and corresponds to the print area in the light emitting element layer.

5. The light emitting display device according to claim 4, wherein the driving element layer includes:
a semiconductor layer on the substrate;
a gate insulating layer on the semiconductor layer;
a gate electrode on the gate insulating layer and overlapped with the semiconductor layer;
an intermediate insulating layer covering the gate electrode;
a source electrode connected to one side of the semiconductor layer, and a drain electrode connected to another side of the semiconductor layer, on the intermediate insulating layer; and
a planarization layer on the source electrode and the drain electrode, and
wherein the light emitting element layer includes:
a first electrode connected to the drain electrode on the planarization layer;
a bank covering circumferences of the first electrode;
an emission layer on the bank and the first electrode; and
a second electrode on the emission layer.

6. The light emitting display device according to claim 5, wherein the encapsulation layer includes:
a first inorganic layer on the second electrode;
an organic layer on the first inorganic layer; and
a second inorganic layer on the organic layer,
wherein the internal dam includes:
the planarization layer;
the bank on the planarization layer; and
a spacer on the bank,
wherein the emission layer, the second electrode and the first inorganic layer are deposited as covering the internal dam,
wherein the organic layer is deposited up to a certain height of an inner sidewall of the internal dam, and
wherein the second inorganic layer covers the internal dam.

7. The light emitting display device according to claim 3, further comprising:
a trench surrounding the internal dam and depressed into the display element layer.

8. The light emitting display device according to claim 7, wherein the trench includes:
a hole trench disposed between the internal dam and the through-hole; and
an inner trench disposed between the internal dam and pixels adjacent to the through-hole in the display area.

9. The light emitting display device according to claim 3, further comprising:
a touch electrode layer between the encapsulation layer and the adhesive layer.

10. The light emitting display device according to claim 9, further comprising:
a polarizing plate between the touch electrode layer and the adhesive layer.
